(19) United States
(12) Patent Application Publication
(10) Pub. No.: US 2011/0199741 A1
(43) Pub. Date: Aug. 18, 2011

(54) FLEXIBLE SUBSTRATE AND DISPLAY DEVICE PROVIDED WITH SAME

(75) Inventor: Shinsuke Yokonuma, Osaka-shi (JP)

(73) Assignee: SHARP KABUSHIKI KAISHA, Osaka-shi, Osaka (JP)

(21) Appl. No.: 13/124,415

(22) PCT Filed: Jul. 14, 2009
(86) PCT No.: PCT/JP2009/062718

§ 371 Date: Apr. 15, 2011

(30) Foreign Application Priority Data
Nov. 19, 2008 (JP) 2008-295738

(51) Int. Cl. H05K 1/00

(52) U.S. Cl. 361/749; 174/254

(57) ABSTRACT

Provided is a flexible substrate wherein disconnection of wiring is suppressed, while reducing unnecessary radiation. A flexible substrate (10) is provided with a flexible base body (11), a plurality of wiring lines (12) formed on an inner surface (11a) of the base body, and a plurality of ground wiring lines (13) formed on an outer surface (11b) of the base body such that the ground wiring lines face the wiring lines (12). In a bent portion (11c) of the base body, the ground wiring lines are formed with a width smaller than that of the wiring lines (12).

### TECHNICAL FIELD

The present invention relates to a flexible substrate (a flexible circuit board) and a display device provided therewith, and particularly relates to a flexible circuit board that includes a base body having wiring lines formed on both sides thereof and a display device provided therewith.

### BACKGROUND ART

In recent years, electronic apparatuses have become compact and their performance has been improved, and this has raised a demand for reduction of unwanted radiation generated from circuit boards incorporated in electronic apparatuses. To fulfill the demand, there has been proposed, for example, a printed circuit board that includes a base body having wiring lines formed on both sides thereof (see, for example, Patent Literature 1 listed below).

The above-mentioned Patent Literature 1 discloses a printed circuit board provided with a printed circuit base material (base body), a power supply pattern (a power supply wiring line) formed on a surface of the printed circuit base material on which an IC (integrated circuit) is to be mounted, and a ground pattern (a ground wiring line) formed on a rear surface of the printed circuit base material so as to be located opposite to the power supply pattern.

In this printed circuit board, by forming the ground pattern on the rear surface of the printed circuit base material so as to be located opposite to the power supply pattern, the power supply pattern and the ground pattern can be electromagnetically coupled to each other. This makes it possible to reduce unwanted radiation generated from the power supply pattern (the printed circuit board).

This printed circuit board makes it possible to reduce unwanted radiation generated from the power supply pattern (the printed circuit board) merely by forming the ground pattern on the rear surface of the printed circuit base material, and thus, with this printed circuit board, in comparison with a case where, for example, an electromagnetic wave absorbing tape or an EMC (electromagnetic compatibility) countermeasure component is additionally provided, unwanted radiation can be easily reduced without increase in size (weight) of the printed circuit board.

Electronic apparatuses provided with a display device such as a liquid crystal display device have been conventionally known, and such electronic apparatuses incorporate a display panel and a flexible circuit board, which is flexible, the flexible circuit board being electrically connected to the display panel.

A possible way to reduce unwanted radiation generated from such an electronic apparatus is to form the flexible circuit board to have the same structure as the printed circuit board disclosed in Patent Literature 1.

That is, to form the flexible circuit board such that it includes a base body having flexibility, a power supply wiring line formed on one surface of the base body, and a ground wiring line formed on the other surface of the base body so as to be opposite to the power supply wiring line. In this way, it is possible to reduce unwanted radiation generated from the flexible circuit board (the electronic apparatus).

### Citation List

### Patent Literature

Patent Literature 1: JP-A-H10-223997

### SUMMARY OF INVENTION

### Technical Problems

However, if a flexible circuit board, which is flexible, is formed to have the same structure as the printed circuit board of Patent Literature 1, when the flexible circuit board is bent, a force is applied to a wiring line (a power supply wiring line or a ground wiring line) that is formed on an outside surface of the base body in a direction to stretch the wiring line. This leads to a possibility that the wiring line (the power supply wiring line or the ground wiring line) formed on the outside surface of the base body is broken, which is disadvantageous.

The present invention has been made to solve the above problems, and an object of the present invention is to provide a flexible circuit board capable of capable of preventing break of wiring lines and capable of reducing unwanted radiation, and a display device provided therewith.

### Solution to Problem

To achieve the above object, according to a first aspect of the present invention, a flexible circuit board includes: a base body that is flexible and includes an inside surface that is located inside when the base body is in a bent state and an outside surface that is located outside when the base body is in the bent state; a set of a plurality of first wiring lines formed on the inside surface of the base body; and a set of a plurality of second wiring lines formed on the outside surface of the base body so as to be opposite to the first wiring lines. Here, one of the set of the first wiring lines and the set of the second wiring lines includes ground wiring lines; and in a bent portion of the base body, the second wiring lines are formed smaller than the first wiring lines in at least one of width and thickness.

With the flexible circuit board according to the first aspect, as described above, by providing the plurality of first wiring lines on the inside surface of the base body and the plurality of second wiring lines on the outside surface of the base body so as to be opposite to the first wiring lines, and by structuring such that one of the set of the first wiring lines and the set of the second wiring lines includes the ground wiring lines, it is possible to electromagnetically couple the first wiring lines to the second wiring lines. With this structure, even in a case where the other of the set of the first wiring lines and the set of the second wiring lines includes a signal wiring line and a power supply wiring line, it is possible to reduce unwanted radiation generated from the other of the set of the first wiring lines and the set of the second wiring lines (specifically, from the signal wiring line and the power supply wiring line).

With the flexible circuit board according to the first aspect, as described above, by forming the second wiring lines smaller than the first wiring lines in at least one of width and thickness in the bent portion of the base body, it is possible to make the second wiring lines easy to be stretched when the base body (the flexible circuit board) is bent. This helps prevent the second wiring lines from being broken.

Furthermore, by forming the second wiring lines smaller than the first wiring lines in at least one of width and thickness in the bent portion of the base body, it is possible to prevent generation of a large reaction force when the base body (the flexible circuit board) is bent. That is, it is possible to prevent the base body (the flexible circuit board) from becoming difficult to be bent.

Preferably, in the above-described flexible circuit board according to the first aspect described above, the first wiring lines include at least one kind of wiring line out of a signal wiring line, a power supply wiring line, and a ground wiring line, and the second wiring lines include the ground wiring lines. With this structure, the at least one kind of wiring line out of a signal wiring line, a power supply wiring line, and a ground wiring line formed on the inside surface of the base body can be easily connected to, for example, a display panel arranged inside from the flexible circuit board in a bent state. Furthermore, since the second wiring lines include the ground wiring lines, even if the second wiring lines (the ground wiring lines) formed on the outside surface of the base body should be broken when the base body is bent, the first wiring lines (the signal wiring line, the power supply wiring line, and the ground wiring line) will not be broken, and this, for example, helps prevent the display panel from ceasing to function properly.

Preferably, in the flexible circuit board according to the first aspect described above, in the base body, a through hole is formed in a portion at a side where one-side ends of the first and second wiring lines are located, and the one-side ends of the second wiring lines are drawn out via the through hole toward the inside surface of the base body. This structure helps electrically connect both the first and second wiring lines easily to, for example, the display panel. As a result, when a current (a signal) flows through the other of the set of the first wiring lines and the set of the second wiring lines, it is easy to make a feedback current (a feedback signal) flow through the one of the set of the first wiring lines and the set of the second wiring lines (the ground wiring lines), and this makes it easy to electromagnetically couple the first wiring lines to the second wiring lines. As a result, unwanted radiation generated from the other of the set of the first wiring lines and the set of the second wiring lines (the signal wiring line, the power supply wiring line, etc.) can be easily reduced.

Preferably, in the flexible circuit board having a through hole formed in the base body thereof, the second wiring lines include the ground wiring lines, and one-side ends of the ground wiring lines are connected to each other. With this structure, it is possible to draw out the ground wiring lines in a collective state toward the inside surface of the base body. This makes it possible to reduce increase in number of through holes formed for drawing out the ground wiring lines therethrough toward the inside surface of the base body, and thus to reduce increase in space for forming the through holes. Thus, the ground wiring lines can be easily drawn out toward the inside surface of the base body.

In the flexible circuit board according to the first aspect described above, there may be formed a solid ground pattern in the base body, such that another-side ends of the ground wiring lines are connected to the solid ground pattern.

According to a second aspect of the present invention, a display device includes: the flexible circuit board structured as described above; and a display panel that is electrically connected to the flexible circuit board. With this structure, it is possible to obtain a display device capable of preventing break of wiring lines and capable of reducing unwanted radiation.

### Advantageous Effects of Invention

As discussed hereinabove, according to the present invention, it is easy to obtain a flexible circuit board capable of preventing break of wiring lines and capable of reducing unwanted radiation and a display device provided with the flexible circuit board.

### BRIEF DESCRIPTION OF DRAWINGS

FIG. 1 A sectional view showing the structure of a liquid crystal display device provided with a flexible circuit board according to an embodiment of the present invention;

FIG. 2 A perspective view showing the structure of the flexible circuit board and the liquid crystal display panel according to the embodiment of the present invention shown in FIG. 1;

FIG. 3 A plan view showing the structure of the flexible circuit board according to the embodiment of the present invention shown in FIG. 1;

FIG. 4 An enlarged see-through view showing the structure of wiring lines formed on an inside surface of the flexible circuit board according to the embodiment of the present invention shown in FIG. 1;

FIG. 5 An enlarged view showing the structure of wiring lines formed on an outside surface of the flexible circuit board according to the embodiment of the present invention shown in FIG. 1;

FIG. 6 A sectional view taken along line 100-100 in FIG. 5;

FIG. 7 A sectional view taken along line 200-200 in FIG. 5;

FIG. 8 A sectional view showing the structure of a flexible circuit board according to a first modified example of the present invention; and

FIG. 9 A sectional view showing the structure of a flexible circuit board according to a second modified example of the present invention.

### DESCRIPTION OF EMBODIMENTS

Embodiments of the present invention will be described below with reference to the drawings.

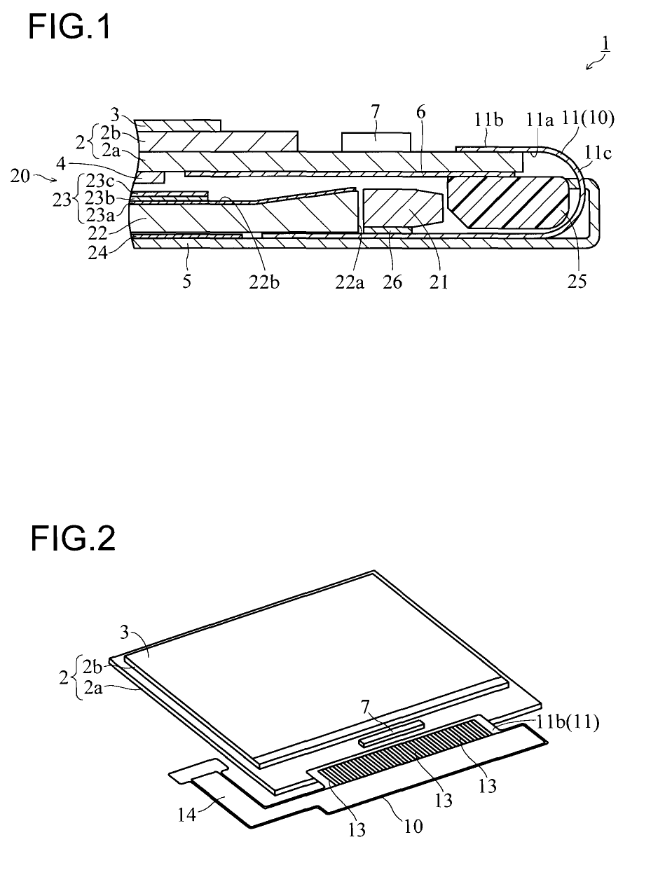

With reference to FIGS. 1 to 7, a description will be given of the structure of a liquid crystal display device 1 provided with a flexible circuit board 10 according to an embodiment of the present invention. The liquid crystal display device 1 is an example of a “display device” of the present invention.

The liquid crystal display device 1 provided with the flexible circuit board 10 according to an embodiment of the present invention is used in electronic apparatuses such as portable phone terminals. In addition, as shown in FIG. 1, the liquid crystal display device 1 includes a liquid crystal display panel 2, an upper polarization plate 3 and a lower polarization plate 4 between which the liquid crystal display panel 2 is placed, a backlight unit 20 arranged at a rear surface side (a lower side) of the liquid crystal display panel 2, and a metal frame 5 that covers a rear surface side of the backlight unit 20. The liquid crystal display panel 2 is an example of a “display panel” of the present invention.

The liquid crystal display panel 2, as shown in FIG. 2, includes a transparent AM substrate (active matrix substrate) 2a and a transparent counter substrate 2b that is arranged opposite to the AM substrate 2a and has a smaller area than the AM substrate 2a. Between the AM substrate 2a and the counter substrate 2b, unillustrated liquid crystal is sealed. The liquid crystal display panel 2 functions as a display panel by being illuminated by the backlight unit 20 (see FIG. 1).

The liquid crystal display panel 2 is, as shown in FIG. 1, adhered (fixed) to a front surface of a frame 25, which will be described later, with an adhesive member 6, which is, for example, a double-faced tape.

To a front surface of the AM substrate 2a, as shown in FIGS. 1 and 2, a driving IC 7 and the flexible circuit board 10 are fitted.

The flexible circuit board 10 includes an insulating base body 11 that has flexibility and that also includes an inside surface 11a (see FIG. 1) that is located inside when the flexible circuit board 10 is in a bent state (the state shown in FIG. 1) and an outside surface 11b that is located outside when the flexible circuit board 10 is in the bent state.

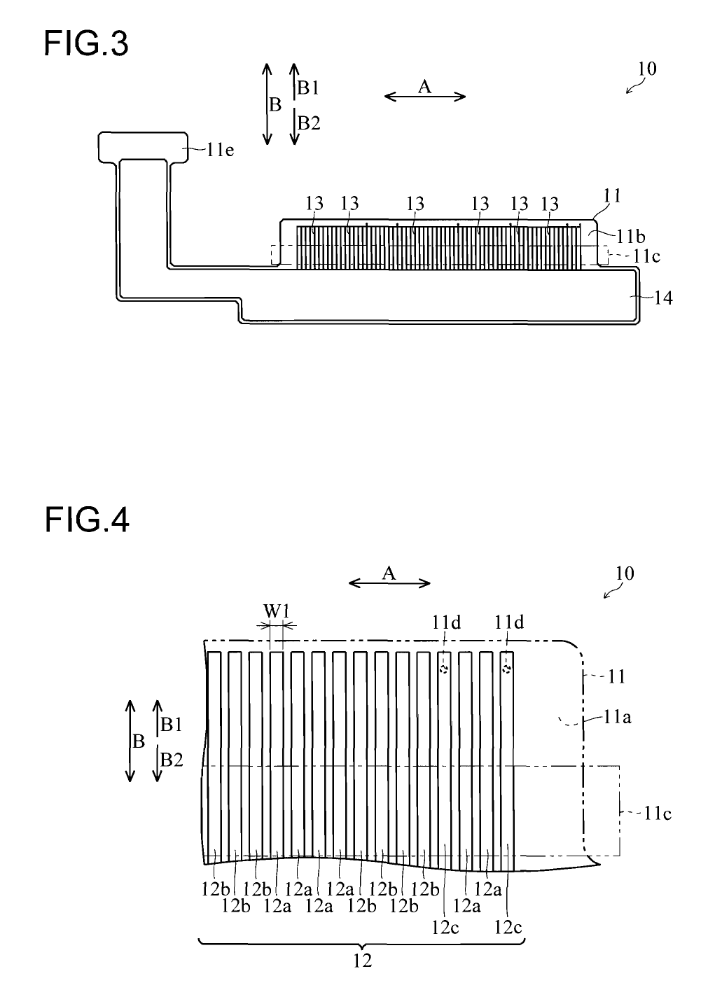

The base body 11 has a bent portion 11c (see FIGS. 1 and 3) that is bent when the flexible circuit board 10 is incorporated in the liquid crystal display device 1.

As shown in FIG. 4, on the inside surface 11a of the base body 11, there are formed a plurality of wiring lines 12. These wiring lines 12 include signal wiring lines 12a, power supply wiring lines 12b, and ground wiring lines 12c, and are arranged with a predetermined pitch in direction A. The wiring lines 12 are an example of “first wiring lines” of the present invention.

The wiring lines 12 are formed so as to extend in direction B across the bent portion 11c of the base body 11. One-side (direction B1-side) ends of the wiring lines 12 are electrically connected to a terminal (not shown) of the liquid crystal display panel 2.

On the other hand, as shown in FIG. 3, on the outside surface 11b of the base body 11, there are formed a plurality of ground wiring lines 13 and a solid ground pattern 14. The ground wiring lines 13 are an example of “second wiring lines” and “ground wiring lines” of the present invention.

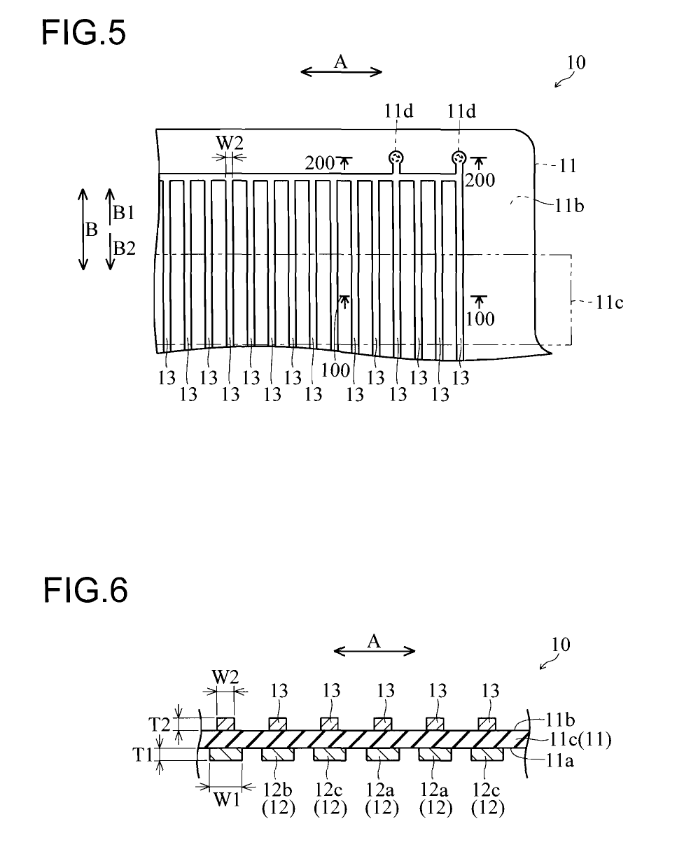

Here, according to the present embodiment, as shown in FIGS. 5 and 6, the plurality of ground wiring lines 13 are formed on the outside surface 11b of the base body 11 so as to be opposite to the plurality of wiring lines 12 (at least all of the signal wiring lines 12a and the power supply wiring lines 12b) (see FIG. 6). That is, the ground wiring lines 13 are formed at positions right behind the wiring lines 12.

The plurality of ground wiring lines 13 are, as shown in FIG. 6, arranged in direction A with the same pitch as the wiring lines 12. As shown in FIG. 5, the ground wiring lines 13 are formed in the same manner as the wiring lines 12, that is, so as to extend in direction B across the bent portion 11c of the base body 11.

According to the present embodiment, as shown in FIG. 6, in the bent portion 11c of the base body 11, a width W2 of the ground wiring lines 13 is smaller than a width W1 of the wiring lines 12. Incidentally, according to the present embodiment, a thickness T2 of the ground wiring lines 13 is equal to a thickness T1 of the wiring lines 12.

According to the present embodiment, as shown in FIG. 5, one-side ends (direction B1-side ends) of the ground wiring lines 13 are connected to each other.

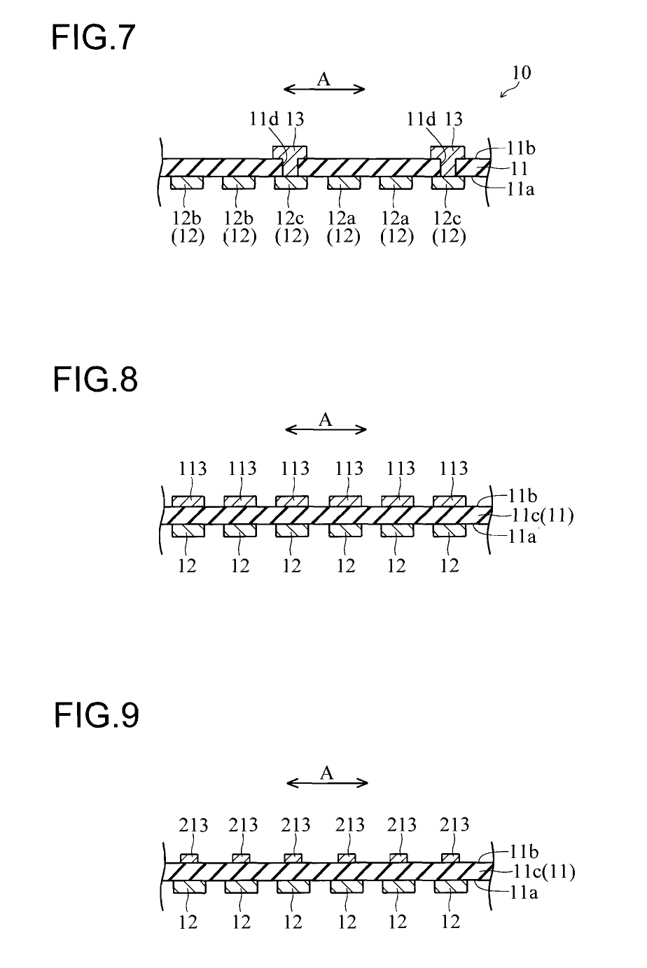

According to the present embodiment, as shown in FIGS. 5 and 7, one-side ends (direction B1-side ends) of the ground wiring lines 13 are drawn out toward the inside surface 11a of the base body 11 via through holes 11d formed in a portion of the base body 11 close to one edge (direction B1 side) thereof. That is, the one-side ends of the ground wiring lines 13 are connected via the through holes 11d to the ground wiring lines 12c included in the wiring lines 12. As a result, the wiring lines 12 and the ground wiring lines 13 are both electrically connected to the liquid crystal display panel 2 (see FIG. 2).

As shown in FIG. 3, another-side ends (direction B2-side ends) of the ground wiring lines 13 are connected to the solid ground pattern 14.

The solid ground pattern 14 formed to range from a region closer to direction B2 side than the bent portion 11c (a side opposite from the liquid crystal display panel 2) to a connector member connection region 11e to which a connector member (not shown) is connected. Incidentally, to the connector member (not shown), the solid ground pattern 14 (the ground wiring lines 13) and the wiring lines 12 (the signal wiring lines 12a, the power supply wiring lines 12b, and the ground wiring lines 12c) are electrically connected.

As shown in FIG. 1, the backlight unit 20 is a side light type (edge light type) backlight unit, and includes a plurality of LEDs (light emitting diodes) 21, a light guide plate 22 having a light receiving surface 22a for receiving light from the LEDs 21, a plurality of optical sheets 23, a reflection sheet 24 arranged at a rear surface side of the light guide plate 22, and a resin frame 25 for housing these.

The plurality of LEDs 21 are fixed on the inside surface 11a of the base body 11 (the flexible circuit board 10) via a solder layer 26.

The light guide plate 22 has a function of receiving light from the LEDs 21 through the light receiving surface 22a thereof and outputting light from a light outputting surface 22b thereof toward the liquid crystal display panel 2.

The plurality of optical sheets 23 are arranged to be in contact with the light guide plate 22. The plurality of optical sheets 23 include, for example, a diffusion sheet 23a that has a function of diffusing light, and lower and upper lens sheets 23b and 23c that are arranged in front of the diffusion sheet 23a and have a function of collecting light.

The reflection sheet 24 reflects light outputted from the rear surface of the light guide plate 22 to make the reflected light travel to the light guide plate 22.

The frame 25 houses the plurality of LEDs 21, the light guide plate 22, the plurality of optical sheets 23, etc.

According to the present embodiment, as described above, by forming a plurality of signal wiring lines 12a and power supply wiring lines 12b on the inside surface 11a of the base body 11, and by forming a plurality of ground wiring lines 13 on the outside surface 11b of the base body 11 so as to be opposite to the signal wiring lines 12a and the power supply wiring lines 12b, the signal and power supply wiring lines 12a and 12b can be electromagnetically coupled to the ground wiring lines 13. This helps reduce unwanted radiation generated from the signal wiring lines 12a and the power supply wiring lines 12b.

Furthermore, according to the present embodiment, as described above, in the bent portion 11c of the base body 11, by making the width W2 of the ground wiring lines 13 smaller than the width W1 of the wiring lines 12, the ground wiring lines 13 formed on the outside surface 11b can be easily stretched when the base body 11 (the flexible circuit board 10) is bent. This helps prevent the ground wiring lines 13 from being broken.

Moreover, by making the width W2 of the ground wiring lines 13 smaller than the width W1 of the wiring lines 12 in the bent portion 11c of the base body 11, it is possible to prevent generation of a large reaction force when the base body 11 (the flexible circuit board 10) is bent. That is, the base body 11 (the flexible circuit board 10) can be prevented from becoming difficult to bend.

According to the present embodiment, as described above, the signal wiring lines 12a and the power supply wiring lines 12b are formed on the inside surface 11a of the base body 11, and the ground wiring lines 13 are formed on the outside surface 11b of the base body 11. With this structure, even if the wiring lines (the ground wiring lines 13) formed on the outside surface 11b of the base body 11 should be broken, the signal wiring lines 12a and the power supply wiring lines 12b will not be broken, and this helps prevent the liquid crystal display panel 2 (the liquid crystal display device 1) ceasing to function properly.

Furthermore, according to the present embodiment, as described above, by drawing out the one-side ends of the ground wiring lines 13 toward the inside surface 11a of the base body 11 via the through holes 11d, both the wiring lines 12 and the ground wiring lines 13 can be electrically connected to the liquid crystal display panel 2 easily. This makes it easy to make a feedback current (a feedback signal) flow through the ground wiring lines 13 when a current (a signal) flows through the wiring lines 12 (the signal wiring lines 12a and the power supply wiring lines 12b), and thus, the wiring lines 12 (the signal wiring lines 12a and the power supply wiring lines 12b) can be electromagnetically coupled to the ground wiring lines 13 easily. As a result, unwanted radiation generated from the wiring lines 12 (the signal wiring lines 12a and the power supply wiring lines 12b) can be easily reduced.

Moreover, according to the present embodiment, as described above, by connecting the one-side ends of the ground wiring lines 13 to each other, the ground wiring lines 13 can be drawn out in a collective state toward the inside surface 11a of the base body 11. This makes it possible to reduce increase of the number of the through holes 11d provided for the ground wiring lines 13 to be drawn out toward the inside surface 11a of the base body 11 therethrough and to prevent increase in space for forming the through holes 11d, and thus the ground wiring lines 13 can be easily drawn out toward the inside surface 11a of the base body 11.

The embodiment disclosed herein is to be considered in all respects as illustrative and not restrictive. The scope of the present invention is set out in the appended claims and not in the description of the embodiment hereinabove, and includes any variations and modifications within the sense and scope equivalent to those of the claims.

For example, the above-described embodiment shows a case where the display device is applied to a liquid crystal display device, but this is not meant to limit the present invention, and application is possible to any type of display device other than a liquid crystal display device.

The above-described embodiment shows a case where the flexible circuit board is connected to the liquid crystal display panel, but this is not meant to limit the present invention, and the flexible circuit board may be connected to a member other than the liquid crystal display panel.

The above-described embodiment shows an example where the ground wiring lines 13, which are formed on the outside surface 11b of the base body 11, are formed such that they have a smaller width than the wiring lines 12 formed on the inside surface 11a of the base body 11, but this is not meant to limit the present invention, and, for example, a first modified example of the present invention shown in FIG. 8 or a second modified example of the present invention shown in FIG. 9 may be adopted. Specifically, as shown in FIG. 8, in the bent portion 11c, ground wiring lines 113 formed on the outside surface 11b of the base body 11 may be formed such that they have a thickness smaller than that of the wiring lines 12 formed on the inside surface 11a of the base body 11. In this case as well, it is possible to reduce the risk of the ground wiring lines 113 being broken when the base body 11 (the flexible circuit board 10) is bent. Alternatively, as shown in FIG. 9, in the bent portion 11c, ground wiring lines 213 formed on the outside surface 11b of the base body 11 may be formed such that they have a width and a thickness smaller than those of the wiring lines 12 formed on the inside surface 11a of the base body 11. In this case, it is possible to further reduce the risk of the ground wiring lines 213 being broken when the base body 11 (the flexible circuit board 10) is bent.

The above-described embodiment shows an example where the wiring lines 12 including the signal wiring lines 12a, the power supply wiring lines 12b, etc. are formed on the inside surface 11a of the base body 11 while the ground wiring lines 13 are formed on the outside surface 11b of the base body 11, but this is not meant to limit the present invention, and the ground wiring lines 13 may be formed on the inside surface 11a of the base body 11 and the wiring lines 12 including the signal wiring lines 12a, the power supply wiring lines 12b, etc. may be formed on the outside surface 11b of the base body 11. In this case, the through holes 11d may be provided on a one-to-one basis for the wiring lines 12 including the signal wiring lines 12a, the power supply wiring lines 12b, etc., and the wiring lines 12 including the signal wiring lines 12a, the power supply wiring lines 12b, etc. may be drawn out toward the inside surface 11a of the base body 11.

The above-described embodiment shows an example where the ground wiring lines 13 are formed to be located opposite to at least all the signal wiring lines 12a and the power supply wiring lines 12b, but this is not meant to limit the present invention, and the ground wiring lines 13 do not need to be formed to be opposite to all of the signal wiring lines 12a and the power supply wiring lines 12b. That is, the ground wiring lines 13 may be formed such that one ground wiring line 13 opposes each of ones of the signal wiring lines 12a and the power supply wiring lines 12b that are likely to generate unwanted radiation.

The above-described embodiment shows an example where the wiring lines 12 formed on the inside surface 11a of the base body 11 include the signal wiring lines 12a, the power supply wiring lines 12b, and the ground wiring lines 12c, but this is not meant to limit the present invention, and the wiring lines 12 may include only the signal wiring lines 12a and the power supply wiring lines 12b. In other words, the ground wiring lines 12c do not need to be formed on the inside surface 11a of the base body 11. In this case, for the purpose of connecting the ground wiring lines 13 to the liquid crystal display panel 2, there may additionally be formed a pattern that functions as ground in part around the through holes 11d on the inside surface 11a of the base body 11.

The above-described embodiment shows an example where only the solid ground pattern 14 is provided on the outside surface 11b of the base body 11 to range from a region closer to direction B side (the side opposite from the liquid crystal display panel 2) than the bent portion 11c to the connector member connection region 11e, but this is not meant to limit the present invention, and a signal wiring line or a power supply wiring line may be provided, for example, in part of the region of the outside surface 11b of the base body 11 where the solid ground pattern 14 is formed. That is, part of the signal wiring lines 12a and the power supply wiring lines 12b that are formed on the inside surface 11a of the base body 11 may be drawn out toward the outside surface 11b of the base body 11 via the through holes. With this structure, a space for fitting components such as a capacitor and a resistor can be easily secured on the inside surface 11a of the base body 11.

Reference Signs List
1 liquid crystal display device (display device)
2 liquid crystal display panel (display panel)
10 flexible circuit board
11 base body
11a inside surface
11b outside surface
11c bent portion
11d through hole
12 wiring line (first wiring line)
12a signal wiring line
12b power supply wiring line
12c ground wiring line
13, 113, 213 ground wiring line (second wiring line, ground wiring line)
14 solid ground pattern

1. A flexible circuit board, comprising:
a base body that is flexible and includes an inside surface that is located inside when the base body is in a bent state and an outside surface that is located outside when the base body is in the bent state;
a set of a plurality of first wiring lines formed on the inside surface of the base body; and
a set of a plurality of second wiring lines formed on the outside surface of the base body so as to be opposite to the first wiring lines,
wherein
one of the set of the first wiring lines and the set of the second wiring lines includes ground wiring lines; and
in a bent portion of the base body, the second wiring lines are formed smaller than the first wiring lines in at least one of width and thickness.

2. The flexible circuit board of claim 1,
wherein
the first wiring lines include at least one kind of wiring line out of a signal wiring line, a power supply wiring line, and a ground wiring line; and
the second wiring lines include the ground wiring lines.

3. The flexible circuit board of claim 1,
wherein,
in the base body, a through hole is formed in a portion at a side where one-side ends of the first and second wiring lines are located; and
the one-side ends of the second wiring lines are drawn out via the through hole toward the inside surface of the base body.

4. The flexible circuit board of claim 3,
wherein
the second wiring lines include the ground wiring lines; and
one-side ends of the ground wiring lines are connected to each other.

5. The flexible circuit board of claim 1,
wherein,
in the base body, a solid ground pattern is formed; and
another-side ends of the ground wiring lines are connected to the solid ground pattern.

6. A display device, comprising:
the flexible circuit board of any one of claims 1; and
a display panel that is electrically connected to the flexible circuit board.

7. The flexible circuit board of claim 2,
wherein,
in the base body, a through hole is formed in a portion at a side where one-side ends of the first and second wiring lines are located; and
the one-side ends of the second wiring lines are drawn out via the through hole toward the inside surface of the base body.

8. The flexible circuit board of claim 7,
wherein
the second wiring lines include the ground wiring lines; and
one-side ends of the ground wiring lines are connected to each other.

9. The flexible circuit board of claim 2,
wherein,
in the base body, a solid ground pattern is formed; and
another-side ends of the ground wiring lines are connected to the solid ground pattern.

10. The flexible circuit board of claim 3,
wherein,
in the base body, a solid ground pattern is formed; and
another-side ends of the ground wiring lines are connected to the solid ground pattern.

11. The flexible circuit board of claim 4,
wherein,
in the base body, a solid ground pattern is formed; and
another-side ends of the ground wiring lines are connected to the solid ground pattern.

12. A display device, comprising:
the flexible circuit board of claim 2; and
a display panel that is electrically connected to the flexible circuit board.

13. A display device, comprising:
the flexible circuit board of claim 3; and

14. A display device, comprising:
the flexible circuit board of claim 4; and
a display panel that is electrically connected to the flexible circuit board.

15. A display device, comprising:
the flexible circuit board of claim 5; and
a display panel that is electrically connected to the flexible circuit board.

16. A display device, comprising:
the flexible circuit board of claim 7; and
a display panel that is electrically connected to the flexible circuit board.

17. A display device, comprising:
the flexible circuit board of claim 8; and
a display panel that is electrically connected to the flexible circuit board.

18. A display device, comprising:
the flexible circuit board of claim 9; and
a display panel that is electrically connected to the flexible circuit board.

19. A display device, comprising:
the flexible circuit board of claim 10; and
a display panel that is electrically connected to the flexible circuit board.

20. A display device, comprising:
the flexible circuit board of claim 11; and
a display panel that is electrically connected to the flexible circuit board.
